(19) United States
(12) Patent Application Publication
(10) Pub. No.: US 2011/0220961 A1
(43) Pub. Date: Sep. 15, 2011

(54) SEMICONDUCTOR DEVICE

(75) Inventor: Hideaki NINOMIYA, Kanagawa-ken (JP)

(73) Assignee: Kabushiki Kaisha Toshiba, Tokyo (JP)

(21) Appl. No.: 13/043,152

(22) Filed: Mar. 8, 2011

(30) Foreign Application Priority Data
Mar. 9, 2010 (JP) 2010-051507

(51) Int. Cl. H01L 29/74

(52) U.S. Cl. 257/132; 257/E29.214

(57) ABSTRACT

According to one embodiment, a semiconductor device includes a first semiconductor region of a first conductivity type, a second semiconductor region of a second conductivity type, a third semiconductor region of the second conductivity type, a fourth semiconductor region of the first conductivity type, a first control electrode, a first main electrode, a fifth semiconductor region of the first conductivity type, a sixth semiconductor region of the second conductivity type, a second main electrode and a semiconductor element. The semiconductor element is connected between the first main electrode and the third semiconductor region. In addition, the semiconductor element includes a channel using part of the first semiconductor region and a second control electrode configured to control the channel on the one major surface of the first semiconductor region.

### CROSS-REFERENCE TO RELATED APPLICATIONS

This application is based upon and claims the benefit of priority from the prior Japanese Patent Application No. 2010-051507, filed on Mar. 9, 2010; the entire contents of which are incorporated herein by reference.

### FIELD

Embodiments described herein relate generally to a semiconductor device.

### BACKGROUND

An IGBT (insulated gate bipolar transistor) has low on-voltage and high breakdown voltage. Thus, the IGBT is widely used as an element for power conversion and control primarily in home electric appliances, communication devices, and vehicle-mounted motors. The operating principle of the IGBT is as follows. The collector electrode of this element is applied with a positive voltage, and the emitter electrode is applied with a negative or zero voltage. In this state, the gate electrode is applied with a positive voltage relative to the emitter electrode. Thus, the oxide film interface side of the P-base layer serves as a channel layer. Hence, an n-type MOSFET (metal oxide semiconductor field effect transistor) is operated, and electron injection is started. The injected electrons are transported to the collector electrode, and holes corresponding to that amount of electrons are injected from the collector electrode. By this injection, the element is placed in the high injection (low on-voltage) state and turned on.

To turn off the element, the gate electrode is applied with 0 V or a negative voltage. This turns off the n-type MOSFET and stops the electron injection. Thus, the hole injection from the collector electrode side is also stopped, and the element is turned off.

Non-Patent Document 1 (“A 4500 V Injection Enhanced Insulated Gate Bipolar Transistor (IEGT) Operating in a Mode Similar to a Thyristor”, M. Kitagawa et al., IEEE IEDM Technical Digest (1993), pp. 679-682) discloses an IEGT (injection enhanced gate transistor). This IEGT includes a region, such as a p-type layer, where holes do not flow. Thus, holes are accumulated on the emitter electrode side of the n-type base layer to promote injection of electrons.

However, a problem is that sufficient breakdown voltage cannot be achieved in the MOS transistor built in the same chip to improve the characteristics of the IEGT. Another problem is that the on-voltage of the diode is difficult to reduce when the IEGT is formed in the reverse conducting structure.

### BRIEF DESCRIPTION OF THE DRAWINGS

FIG. 1 is a schematic sectional view illustrating an example of a semiconductor device according to a first embodiment;

FIGS. 2 to 4 are sectional views illustrating a method for manufacturing a semiconductor device according to the embodiment;

FIG. 5 is a schematic sectional view of a semiconductor device (IGBT) according to a comparative example;

FIG. 6 shows the current variation with respect to time during recovery operation in the structure of the comparative example;

FIGS. 7A and 7B illustrate an example (I) of the built-in configuration of the P-type MOSFET of the semiconductor device according to the embodiment;

FIGS. 8A and 8B illustrate an example (II) of the built-in configuration of the P-type MOSFET of the semiconductor device according to the embodiment;

FIG. 9 illustrates a semiconductor device according to a second embodiment; and

FIGS. 10A and 10B are schematic views illustrating the flow of carriers at the time of diode operation and recovery operation.

### DETAILED DESCRIPTION

In general, according to one embodiment, a semiconductor device includes a first semiconductor region of a first conductivity type, a second semiconductor region of a second conductivity type, a third semiconductor region of the second conductivity type, a fourth semiconductor region of the first conductivity type, a first control electrode, a first main electrode, a fifth semiconductor region of the first conductivity type, a sixth semiconductor region of the second conductivity type, a second main electrode and a semiconductor element.

The second semiconductor region is formed in a part of one major surface of the first semiconductor region.

The third semiconductor region is formed in a part of a region of the one major surface of the first semiconductor region, and the second semiconductor region is not formed in the region.

The fourth semiconductor region is formed in a part of a major surface of the second semiconductor region.

The first control electrode is formed between the second semiconductor region and the third semiconductor region and formed via an insulating film inside a trench in contact with the fourth semiconductor region.

The first main electrode is electrically connected to the second semiconductor region and the fourth semiconductor region.

The fifth semiconductor region is formed on the other major surface opposite from the one major surface of the first semiconductor region.

The sixth semiconductor region is formed on the fifth semiconductor region.

The second main electrode is electrically connected to the sixth semiconductor region.

The semiconductor element is connected between the first main electrode and the third semiconductor region. In addition, the semiconductor element includes a channel using part of the first semiconductor region and a second control electrode configured to control the channel on the one major surface of the first semiconductor region.

Various embodiments will be described hereinafter with reference to the accompanying drawings. By way of illustration, the following description uses an example in which the first conductivity type is n-type and the second conductivity type is p-type. For clarity of description, the figures described below show the portion of one element (cell) in the semiconductor device. However, the semiconductor device of the embodiments can include one or more such elements. In the following description, the “channel” refers to a region of the inversion layer formed upon application of a gate voltage.

### First Embodiment

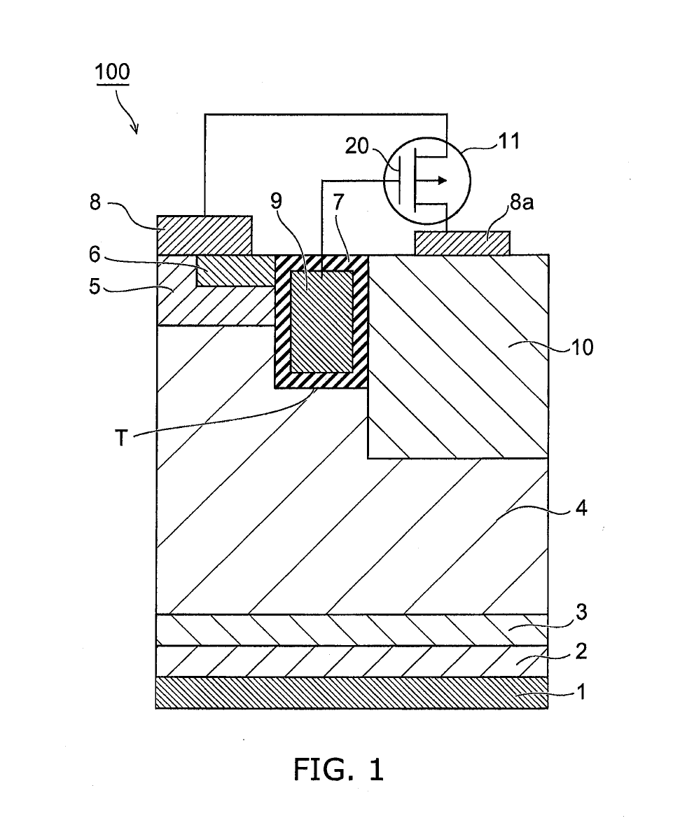

FIG. 1 is a schematic sectional view illustrating an example of a semiconductor device according to a first embodiment.

In the first embodiment, an application to an IGBT (insulated gate bipolar transistor), particularly to an IEGT (injection enhanced gate transistor), is described as an example of the semiconductor device. This semiconductor device 100 includes an N-type base layer 4 as a first semiconductor region, a p-type base layer 5 as a second semiconductor region, a p-type layer 10 as a third semiconductor region, an n-type source layer 6 as a fourth semiconductor region, a gate electrode 9 as a first control electrode, an emitter electrode 8 as a first main electrode, an n-type buffer layer 3 as a fifth semiconductor region, a p-type collector layer 2 as a sixth semiconductor region, a collector electrode 1 as a second main electrode, and a p-type MOSFET (metal oxide semiconductor field effect transistor) 11 as a semiconductor element.

The n-type base layer 4 is a region made of a semiconductor such as silicon. In one major surface thereof (the upper major surface in the figure), a p-type base layer 5 is selectively formed. In the region of the one major surface of the n-type base layer 4 where the p-type base layer 5 is not formed, the p-type layer 10 is selectively formed. The p-type layer 10 is formed deeper than the trench T of the gate electrode 9 described later.

The gate electrode 9 is buried via a gate insulating film 7 in a trench T formed from the surface to the inside of the n-type base layer 4. The trench T is formed between the p-type base layer 5 and the p-type layer 10 and separates them. The depth of the trench T from the one major surface of the n-type base layer 4 is deeper than the depth of the p-type base layer 5 and shallower than the depth of the p-type layer 10. The gate insulating film 7 is a silicon oxide film formed by e.g. heat treatment on the inner wall of the trench T. The gate electrode 9 is made of a conductive material such as polysilicon.

The n-type buffer layer 3 is formed on the other major surface (the lower major surface in the figure) opposite from the one major surface of the n-type base layer 4. The p-type collector layer 2 is formed on the n-type buffer layer 3. The collector electrode 1 is electrically connected to this p-type collector layer 2.

In the semiconductor device 100 of the embodiment, the p-type MOSFET 11 is connected as a switching element between the emitter electrode 8 and the p-type layer 10. In the p-type MOSFET 11, a gate electrode 20 equipotential to the gate electrode 9 is used as a control electrode. Thus, the p-type MOSFET 11 switches the electrical connection state between the emitter electrode 8 and the p-type layer 10. The on/off operation of the p-type MOSFET 11 is opposite to that of the n-type MOSFET composed of the gate electrode 9, the gate insulating film 7, the n-type source layer 6, the p-type base layer 5, and the n-type base layer 4. That is, when the gate electrode 20 is applied with the same potential as the gate electrode 9, the on/off operation of the p-type MOSFET 11 is opposite to that of the n-type MOSFET.

Furthermore, this p-type MOSFET 11 uses part of the n-type base layer 4 as a channel, and includes a gate electrode 20 for controlling this channel on the one major surface of the n-type base layer 4. By using part of the n-type base layer 4 as a channel of the p-type MOSFET 11, the potential of the channel region is stabilized, and the occurrence of latch-up due to a parasitic thyristor is suppressed. Thus, the breakdown voltage of the IGBT (IEGT) including the p-type MOSFET 11 can be improved.

### (Method for Manufacturing a Semiconductor Device)

Next, a method for manufacturing a semiconductor device according to the embodiment is described.

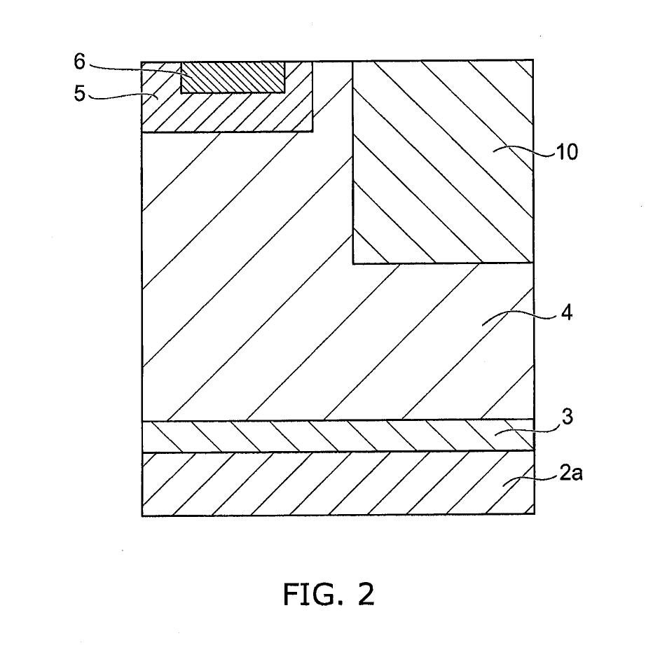

FIGS. 2 to 4 are sectional views illustrating the method for manufacturing a semiconductor device according to the embodiment. First, as shown in FIG. 2, a p-type substrate 2a is prepared. The p-type substrate 2a is e.g. a silicon substrate uniformly doped with p-type impurity. The thickness thereof is e.g. several hundred μm.

Next, on the p-type substrate 2a, an n-type buffer layer 3 and an n-type base layer 4 made of silicon doped with n-type impurity are formed. Here, the impurity concentration of the n-type base layer 4 is made lower than the impurity concentration of the n-type buffer layer 3. Thus, the resistivity of the n-type base layer 4 is made higher than that of the n-type buffer layer 3. Then, by normal methods, a p-type base layer 5 is formed by ion implantation and diffusion in part of one major surface of the n-type base layer 4, and a p-type layer 10 is selectively formed in the region where the p-type base layer 5 is not formed. Here, the p-type layer 10 is formed deeper than the p-type base layer 5. Furthermore, an n-type source layer 6 is formed by ion implantation in part of the major surface of the p-type base layer 5.

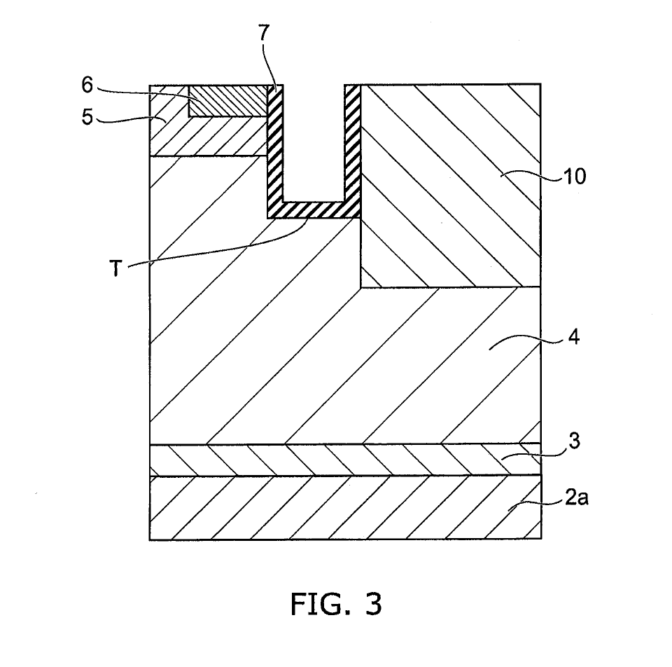

Next, as shown in FIG. 3, a trench T is formed from the one major surface to the inside of the n-type base layer 4. The trench T is formed deeper than the p-type base layer 5 and shallower than the p-type layer 10. By this trench T, the p-type base layer 5 and the n-type source layer 6 are separated from the p-type layer 10. Then, by heat treatment in an oxidizing atmosphere, for instance, a gate insulating film 7 made of silicon oxide is formed on the inner surface of the trench T.

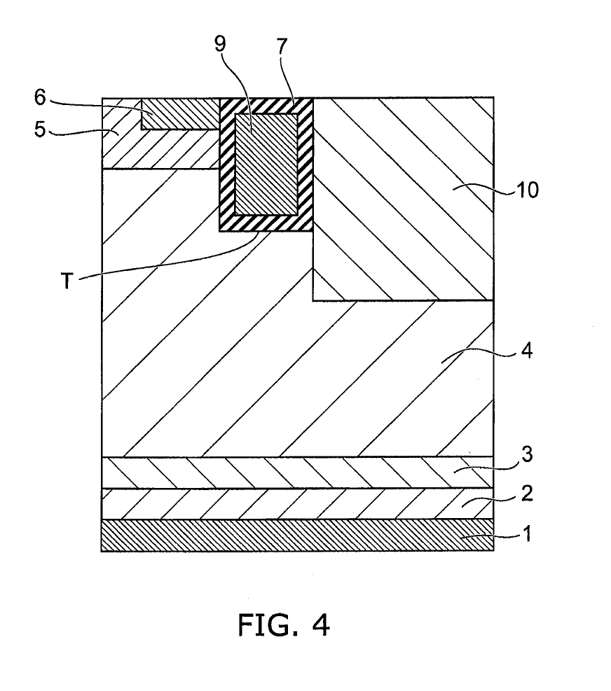

Next, as shown in FIG. 4, a conductive material made of e.g. polysilicon is buried inside the trench T. Subsequently, the conductive material deposited above the trench T is removed. Thus, a gate electrode 9 is formed.

Next, the lower surface of the p-type substrate 2a (see FIG. 3) is ground, for instance, to reduce the thickness of the p-type substrate 2a to a prescribed thickness. Thus, a p-type collector layer 2 is formed. Subsequently, a TEOS (tetraethyl orthosilicate) film, for instance, is formed on the stacked body and patterned so as to be selectively left only in a region including immediately above the gate electrode 9. Thus, a gate insulating film 7 on the gate electrode 9 is formed.

Then, as shown in FIG. 1, an emitter electrode 8 in contact with the p-type base layer 5 and the n-type source layer 6 is formed. On the other hand, a collector electrode 1 is formed on the other major surface (rear surface) of the p-type collector layer 2. Thus, an IGBT (IEGT) structure is completed.

In the embodiment, in the process for manufacturing such an IGBT (IEGT) structure, the p-type MOSFET 11 shown in FIG. 1 is built in the IGBT (IEGT) structure. The p-type MOSFET 11 is built in the structure so as to be connected between the emitter electrode 8 and the electrode 8a connected to the p-type layer 10.

This p-type MOSFET 11 uses part of the n-type base layer 4 as a channel. Furthermore, the p-type base layer 5 or the p-type layer 10 is used as the source or drain of the p-type MOSFET 11. More specifically, the p-type base layer 5 and the p-type layer 10 are formed in part of the major surface of the n-type base layer 4. The region where the p-type base layer 5 and the p-type layer 10 are not formed (the region where the n-type base layer 4 is left) is used as a channel of the p-type MOSFET 11. Furthermore, the p-type base layer 5 or the p-type layer 10 adjacent to the region where the n-type base layer 4 is left is used as the source or drain of the p-type MOSFET 11. The gate electrode 20 of the p-type MOSFET 11 is formed in a planar configuration via a gate insulating film on the n-type base layer 4 used as a channel. Thus, the semiconductor device 100 of the embodiment including the p-type MOSFET 11 in an IGBT configuration is completed.

### (Operation of the Semiconductor Device)

Next, the operation of the semiconductor device 100 according to the embodiment is described.

First, to turn on, the collector electrode 1 is applied with a positive voltage, and the emitter electrode 8 is applied with a negative or zero voltage. In this state, the gate electrode 9 is applied with a positive voltage relative to the emitter electrode 8. Thus, the gate oxide film 7 interface side of the p-type base layer 5 serves as a channel layer. Hence, the n-type MOSFET is operated, and electron injection is started.

At this time, the gate electrode 20 equipotential to the gate electrode 9 is also applied with a positive voltage relative to the emitter electrode 8. Thus, the p-type MOSFET 11 is turned off, and the path between the emitter electrode 8 and the p-type layer 10 is placed in the insulating state. Hence, holes are accumulated on the emitter electrode 8 side of the n-type base layer 4, and injection of electrons is promoted. Then, the injected electrons are transported to the collector electrode 1, and holes corresponding to that amount of electrons are injected from the collector electrode 1. Thus, the element is placed in the high injection (low on-voltage) state and turned on.

To turn off, the gate electrode 9 is applied with 0 V or a negative voltage. This turns off the n-type MOSFET and stops the electron injection. Thus, the hole injection from the collector electrode side 1 is also stopped, and the element is turned off. At this time, the gate electrode 20 equipotential to the gate electrode 9 is also applied with 0 V or a negative voltage. This turns on the p-type MOSFET 11. Thus, the path between the emitter electrode 8 and the p-type layer 10 is placed in the conducting state. Hence, holes are ejected to the emitter electrode 8 from the p-type layer 10 formed deeper than the gate electrode 9. That is, as compared with the case of ejecting holes from only the p-type base layer 5, holes are ejected in a shorter time, and the switching loss is reduced.

### Comparative Example

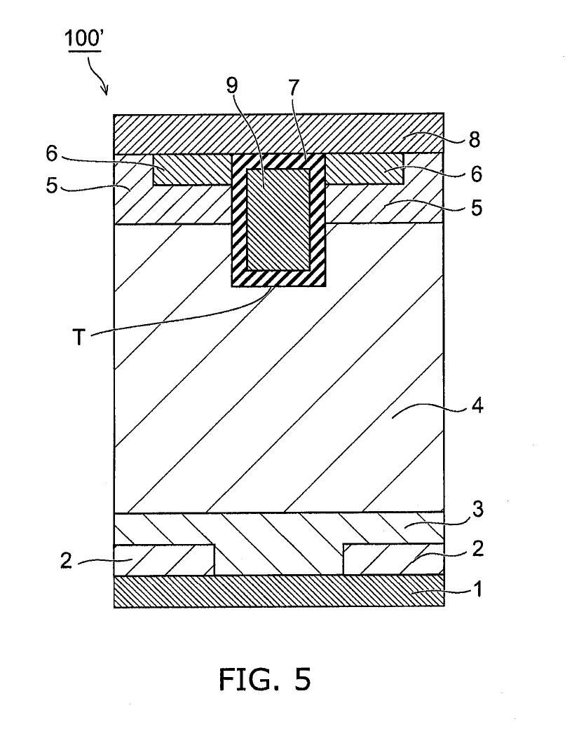

FIG. 5 is a schematic sectional view of a semiconductor device (IGBT) according to a comparative example.

The semiconductor device 100′ according to the comparative example includes a collector electrode 1, a p-type collector layer 2, an n-type buffer layer 3, an n-type base layer 4, a p-type base layer 5, an n-type source layer 6, an emitter electrode 8, a gate electrode 9, and a gate insulating film 7.

In this semiconductor device 100′, the p-type base layer 5 is formed in one major surface of the n-type base layer 4. The n-type source layer 6 is selectively formed in the surface of the p-type base layer 5. A trench T is formed from the surface to the n-type base layer 4 so as to divide the p-type base layer 5 and the n-type source layer 6. In this trench T, the gate electrode 9 is buried via the gate insulating film 7.

The n-type buffer layer 3 is formed on the other major surface of the n-type base layer 4. The p-type collector layer 2 is selectively formed on this n-type buffer layer 3. The collector electrode 1 is connected to the n-type buffer layer 3 and the p-type collector layer 2. That is, part of the n-type buffer layer 3 is connected to the p-type collector layer 2, and another part of the n-type buffer layer 3 is connected to the collector electrode 1. By such a structure, the semiconductor device 100′ according to the comparative example is configured as a reverse conducting IGBT.

The operating principle of this semiconductor device 100′ is as follows. First, the collector electrode 1 is applied with a positive voltage, and the emitter electrode 8 is applied with a negative or zero voltage. In this state, the gate electrode 9 is applied with a positive voltage relative to the emitter electrode 8. Then, the oxide film interface side of the p-base layer 5 serves as a channel layer. Hence, an n-type MOSFET is operated, and electron injection is started. The injected electrons are transported to the collector electrode 1, and holes corresponding to that amount of electrons are injected from the collector electrode 1. Thus, the element is placed in the high injection (low on-voltage) state and turned on.

To turn off the semiconductor device 100′, the gate electrode 9 is applied with 0 V or a negative voltage. This turns off the n-type MOSFET and stops the electron injection. Thus, the hole injection from the collector electrode 1 side is also stopped, and the element is turned off.

This IGBT has the above operating mechanism. However, the amount of electron injection on the emitter electrode side depends on the characteristics of the n-type MOSFET, and it is difficult to achieve sufficiently high injection. Thus, as in the IEGT disclosed in Non-Patent Document 1, part of the p-type base layer 5 is used as a p-type layer where holes do not flow. Thus, holes are accumulated on the emitter electrode side of the n-type base layer. This provides the effect of promoting injection of electrons. The effect of promoting electron injection of the IEGT disclosed in this case increases with the increase of the resistance component of the n-type base layer 4 immediately below the P-type base layer 5 sandwiched between the trenches.

However, the IEGT structure is a structure in which electrons and holes are accumulated on the emitter electrode 8 side. Hence, when the element is turned off, ejection of holes is insufficient. This slows down the switching speed and increases the switching loss. Furthermore, as shown in FIG. 5, part of the n-type buffer layer 3 is connected directly to the collector electrode 1 to form a reverse conducting IGBT structure in which the collector electrode 1 is connected to the n-type buffer layer 3. In this case, in the IEGT structure including a p-type layer, the area of the p-base layer 5 serving as a p-type anode layer in diode operation is small. Hence, unfortunately, the on-voltage of the diode increases.

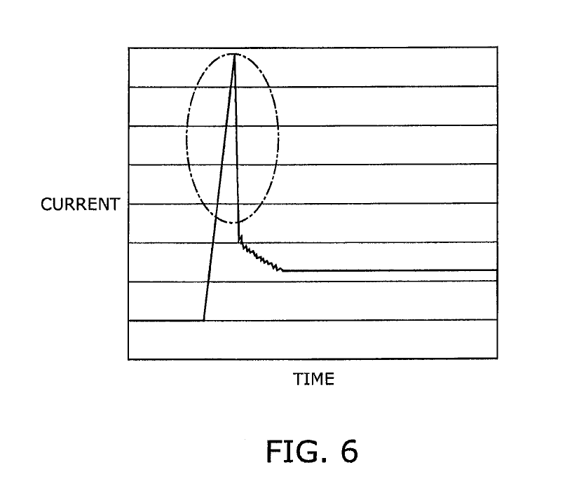

FIG. 6 shows the current variation with respect to time during recovery operation in the structure of the comparative example. In the structure of the comparative example with importance placed on the on-voltage of the IGBT, carriers are stored on the emitter side. This increases Qrr (the amount of accumulated charge) during the recovery operation of the IGBT. As a result, large Irr (reverse current) flows at recovery time (the dot-dashed circle in the figure). This causes switching loss at recovery time.

Thus, in the semiconductor device of the IGBT structure according to the comparative example, it is difficult to decrease the on-voltage. Hence, in the IEGT structure with the P-type base layer partly omitted, it takes a long time to eject carriers at turn-off time. This causes a problem of increased switching loss. Furthermore, in the case of the IEGT in the reverse conducting structure, the area of the p-type anode layer is small. This causes another problem of being difficult to reduce the on-voltage of the diode.

In contrast, the configuration of the semiconductor device 100 of the embodiment described above can provide an IGBT (IEGT) with reduced turn-off loss. Furthermore, a reverse conducting structure can be used on the collector side (see the semiconductor device 200 described later) to provide a reverse conducting IGBT (IEGT) in which the on-voltage of the diode is reduced. That is, even in the IEGT structure with the p-type base layer partly omitted, it is possible to provide a reverse conducting IGBT (IEGT) in which the on-voltage of the semiconductor device is reduced and the diode characteristics are improved by control of the p-type MOSFET.

### (Built-in Configuration of the P-Type MOSFET: I)

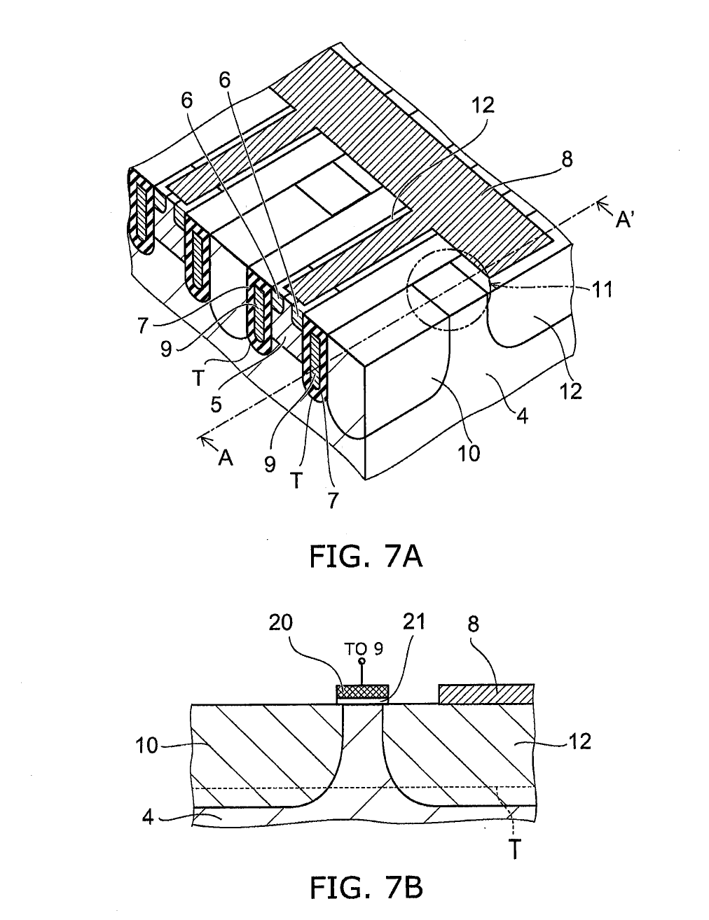

FIGS. 7A and 7B illustrate an example (I) of the built-in configuration of the p-type MOSFET of the semiconductor device according to the embodiment. Here, FIG. 7A is a sectional perspective view, and FIG. 7B is a sectional view on arrow taken along line A-A′ of FIG. 7A. For clarity of description, in FIG. 7A, the gate electrode 20 shown in FIG. 7B is omitted.

In this example (I) of the built-in configuration of the p-type MOSFET, the p-type layer 10 is selectively formed in the n-type base layer 4 along the extending direction of the gate electrode 9. Furthermore, the p-type layer 10 is adjacent to another p-type layer (seventh semiconductor region) 12 across the n-type base layer 4. This n-type base layer 4 between the p-type layer 10 and the p-type layer 12 is used as a channel of the p-type MOSFET 11 (inside the circle in the figure). The p-type layer 12 may be formed in the same process as the p-type layer 10. The p-type layer 12 may be provided to the same depth as the p-type layer 10, or deeper or shallower than the p-type layer 10. Furthermore, the p-type layer 12 does not necessarily need to be in contact with both sides of the trench T. Thus, in the p-type MOSFET 11, the p-type layer 10 serves as a drain, the p-type layer 12 serves as a source, and the n-type base layer 4 located therebetween serves as a channel.

As shown in FIG. 7B, the gate electrode 20 is formed via a gate insulating film 21 on the n-type base layer 4 serving as a channel of the p-type MOSFET 11. Because the n-type base layer 4 serving as a channel is located at the surface, the gate electrode 20 formed thereon is of the planar type.

The gate electrode 20 of the p-type MOSFET 11 and the gate electrode 9 of the IGBT are connected so as to be equipotential. The gate electrode 20 of the p-type MOSFET 11 may be manufactured in the same process as the gate electrode 9 of the IGBT. Furthermore, the gate insulating film 21 may be manufactured in the same process as the gate insulating film 7 formed on the trench T.

The emitter electrode 8 formed on the p-type base layer 5 is provided to extend on the p-type layer 12 serving as the source of the p-type MOSFET 11, and doubles as a source electrode. On the other hand, there is no need to provide an electrode on the p-type layer 10 serving as the drain. This is because the p-type layer 10 is adjacent to the n-type base layer 4 serving as a channel, and hence the p-type layer 10 serves as the drain. Thus, in this configuration, the p-type MOSFET 11 is formed between the emitter electrode 8 and the p-type layer 10. In this structure, the p-type MOSFET 11 is provided on the p-type layer 10 side. Hence, advantageously, the p-type MOSFET 11 can be built in without affecting the characteristics of the n-type MOSFET in the IGBT (IEGT) structure. Furthermore, the p-type layer 12 has the same structure as the p-type base layer 5. Hence, in a reverse conducting IGBT (IEGT), the p-type layer 12 functions as a p-type layer of the diode in conjunction with the p-type base layer 5.

### (Built-in Configuration of the P-Type MOSFET: II)

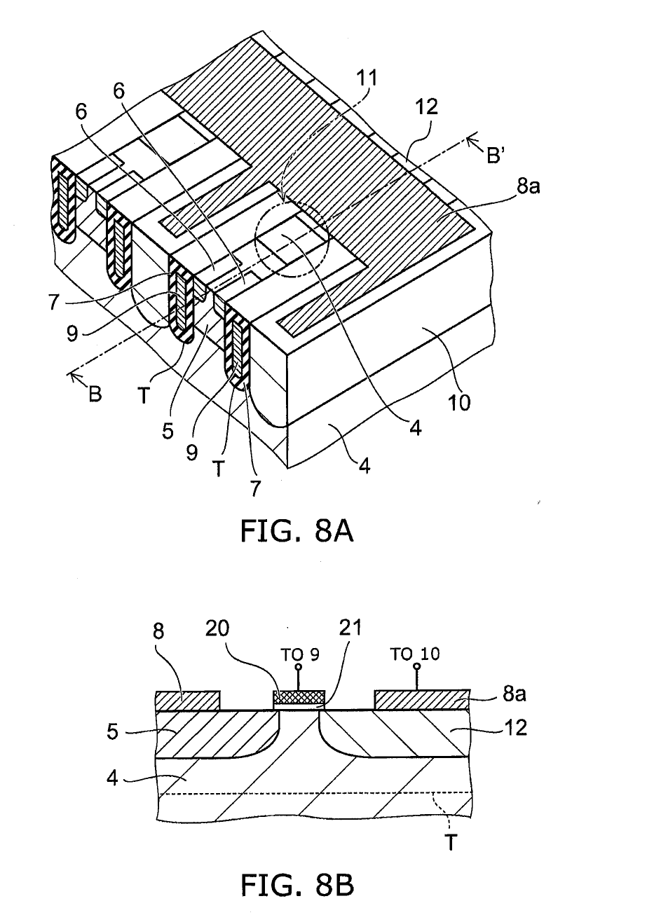

FIGS. 8A and 8B illustrate an example (II) of the built-in configuration of the p-type MOSFET of the semiconductor device according to the embodiment. Here, FIG. 8A is a sectional perspective view, and FIG. 8B is a sectional view on arrow taken along line B-B′ of FIG. 8A. For clarity of description, in FIG. 8A, the emitter electrode 8 and the gate electrode 20 shown in FIG. 8B are omitted.

In this example (II) of the built-in configuration of the p-type MOSFET, the n-type base layer 4 used as a channel of the p-type MOSFET 11 is provided adjacent to the p-type base layer 5 (inside the circle in the figure). On the opposite side of this portion of the n-type base layer 4 serving as a channel from the p-type base layer 5, another p-type layer 12 is provided. The p-type layer 12 is located between the adjacent trenches T. This p-type layer 12 may be formed in the same process as the p-type base layer 5. The p-type layer 12 may be provided to the same depth as the p-type base layer 5, or deeper or shallower than the p-type base layer 5. Furthermore, the p-type layer 12 does not necessarily need to be in contact with both sides of the trench T. Thus, in the p-type MOSFET 11, the p-type layer 12 serves as a drain, the p-type base layer 5 serves as a source, and the n-type base layer 4 located therebetween serves as a channel. Here, the p-type layer 12 is connected to the p-type layer 10 by the electrode 8a. Thus, like the p-type layer 12, the p-type layer 10 functions as a drain of the p-type MOSFET 11.

As shown in FIG. 8B, the gate electrode 20 is formed via a gate insulating film 21 on the n-type base layer 4 serving as a channel of the p-type MOSFET 11. Because the n-type base layer 4 serving as a channel is located at the surface, the gate electrode 20 formed thereon is of the planar type.

The gate electrode 20 of the p-type MOSFET 11 and the gate electrode 9 of the IGBT are connected so as to be equipotential. The gate electrode 20 of the p-type MOSFET 11 may be manufactured in the same process as the gate electrode 9 of the IGBT. Furthermore, the gate insulating film 21 may be manufactured in the same process as the gate insulating film 7 formed on the trench T.

As a source electrode of the p-type MOSFET 11, the emitter electrode 8 formed on the p-type base layer 5 is used. As a drain electrode of the p-type MOSFET 11, the electrode 8a extending from above the p-type layer 12 to the p-type layer 10 is used. Thus, in this configuration, the p-type MOSFET 11 is formed between the emitter electrode 8 and the p-type layer 10. In this structure, advantageously, the p-type MOSFET 11 can be built in without affecting the size of the p-type layer 10.

In either of the above built-in configurations of the p-type MOSFET 11, part of the n-type base layer 4 is used as a channel of the p-type MOSFET 11. Thus, the potential of the channel region can be stabilized. Hence, the occurrence of latch-up due to a parasitic thyristor is suppressed. Thus, the breakdown voltage of the IGBT (IEGT) including the p-type MOSFET 11 can be improved. The built-in configuration of the p-type MOSFET 11 is not limited to those shown in the above examples I and II, but may have other configurations.

### Second Embodiment

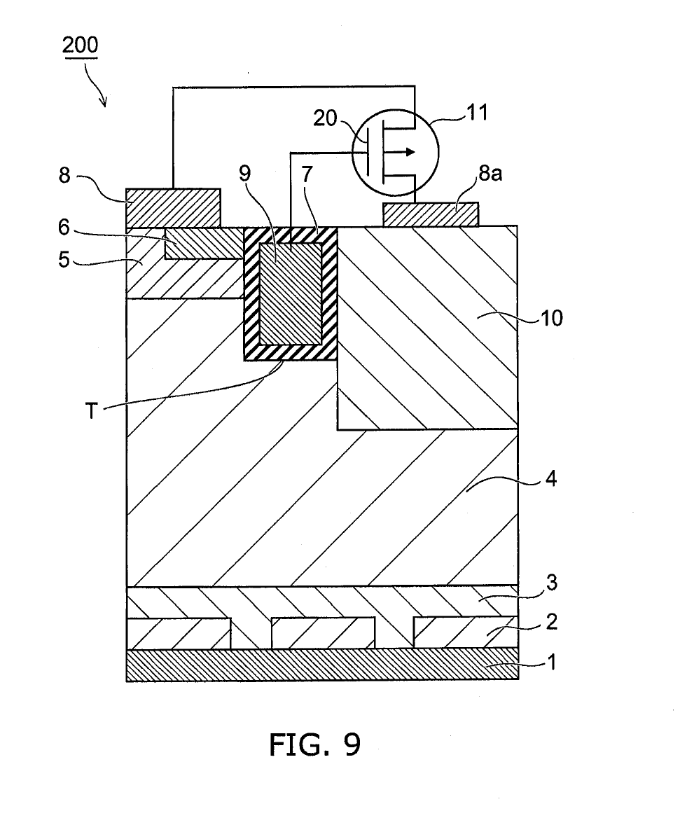

FIG. 9 illustrates a semiconductor device according to a second embodiment.

Here, components similar to those of the semiconductor device shown in FIG. 1 are labeled with like reference numerals, and the detailed description thereof is omitted. The semiconductor device 200 according to the second embodiment is different from the semiconductor device 100 according to the first embodiment in that the n-type buffer layer 3 is connected not only to the p-type collector layer 2 but also partly in direct connection to the collector electrode 1.

To realize such a structure, when the n-type buffer layer 3 is formed on the p-type substrate, the n-type buffer layer 3 is deeply formed only in the portion brought into contact with the collector electrode 1. Subsequently, when the p-type substrate is subjected to thickness reduction processing, the p-type substrate is processed to the position where the n-type buffer layer 3 formed deeply in part is exposed. Then, a collector electrode 1 is formed on the processed surface. This structure of the n-type buffer layer 3 provides the configuration of a reverse conducting IGBT (IEGT) structure.

### (Operation of the Semiconductor Device)

Next, the operation of the semiconductor device 200 according to the embodiment is described.

First, in the operation as an IGBT (IEGT), the gate electrode 9 is applied with a positive voltage relative to the emitter electrode 8. By this voltage application, the p-type MOSFET 11 is turned off, and the path between the emitter electrode 8 and the p-type layer 10 is placed in the insulating state. Then, holes injected from the collector electrode 1 side are accumulated on the emitter electrode 8 side of the n-type base layer 4. This promotes electron injection from the n-type source layer 6 and achieves low on-voltage characteristics.

On the other hand, in the operation as a diode in which the potential on the emitter electrode 8 side is higher than on the collector electrode 1 side, the gate electrode 9 is applied with 0 V or a negative voltage. By this voltage application, the p-type MOSFET 11 is turned on, and the path between the emitter electrode 8 and the p-type layer 10 is placed in the conducting state. Thus, the area of the p-type layer is increased, and the on-voltage of the diode is reduced.

Here, in the case where the p-type layer 10 is provided deeper than the gate electrode 9, carriers are likely to accumulate in the p-type layer 10 and lead to reduction of on-resistance and high breakdown voltage in diode operation. However, because carriers are likely to accumulate, this configuration incurs switching loss during recovery operation if left as it is.

Thus, at the time of recovery operation when the voltage on the collector electrode 1 side is again made higher than on the emitter electrode 8 side, the gate electrode 9 is applied with a positive voltage immediately before entering the recovery operation to turn off the p-type MOSFET 11. Hence, the recovery operation is performed after decreasing carriers in the p-type layer 10. Thus, the switching loss can be reduced.

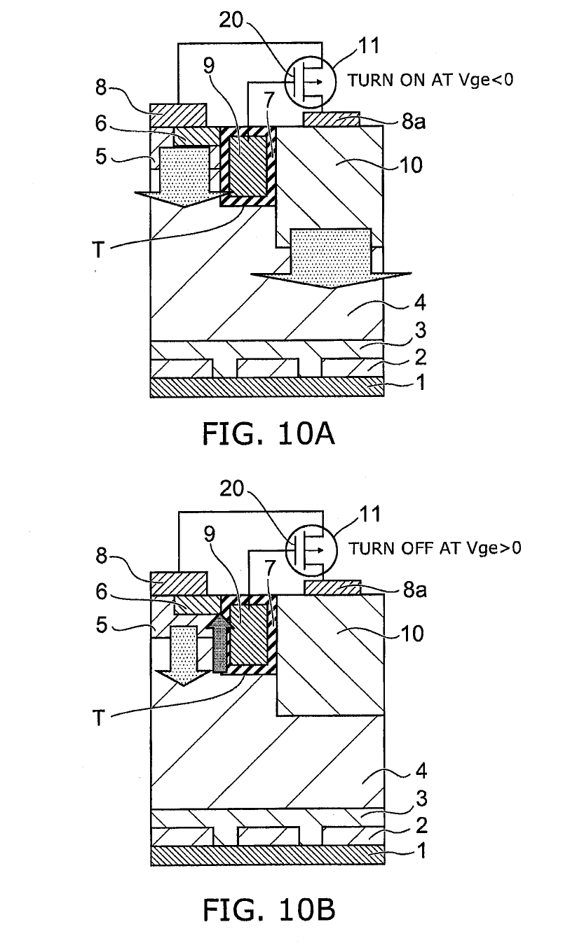

FIGS. 10A and 10B are schematic views illustrating the flow of carriers at the time of diode operation and recovery operation. As shown in FIG. 10A, at the time of diode operation, the p-type MOSFET 11 is turned on, and the path between the emitter electrode 8 and the p-type layer 10 is placed in the conducting state. Thus, both the p-type base layer 5 and the p-type layer 10 function as a p-type layer in the diode. Hence, holes are injected into both the p-type base layer 5 and the p-type layer 10. This results In a lower on-voltage than in the case of injection from only the p-type base layer 5. In particular, in the case where the p-type layer 10 is provided deeper than the gate electrode 9, carriers are likely to accumulate in the p-type layer 10 and lead to reduction of on-resistance and high breakdown voltage.

On the other hand, as shown in FIG. 10B, at the time of recovery operation, the gate electrode 9 is applied with a positive voltage. Thus, the p-type MOSFET 11 is turned off, and the path between the emitter electrode 8 and the p-type layer 10 is placed in the insulating state. Hence, carriers on the emitter electrode 8 side decrease, and Qrr (the amount of accumulated charge) is made smaller. This suppresses flow of high current at recovery time. Thus, the switching loss at recovery time is suppressed.

As described above, the embodiment can achieve compatibility between IGBT (IEGT) characteristics and diode characteristics in the reverse conducting IGBT (IEGT).

The embodiments of the invention and the variations thereof have been described above. However, the invention is not limited to these examples. For instance, those skilled in the art can modify the above embodiments or the variations thereof by suitable addition, deletion, or design change of components, or by suitable combination of the features of the embodiments. Such modifications are also encompassed within the scope of the invention as long as they fall within the spirit of the invention.

For instance, in the above description of the embodiments and variations, the first conductivity type is n-type, and the second conductivity type is p-type. However, the invention can be practiced also in the case where the first conductivity type is p-type and the second conductivity type is n-type. Furthermore, in the embodiments described above, the gate electrode 9 is based on the trench gate structure.

However, the invention is generally applicable to semiconductor devices having the trench MOS gate structure such as vertical trench IGBT and lateral trench IGBT. Furthermore, in the above description of the MOS transistor, the gate insulating film in the semiconductor device is made of a silicon oxide film. However, the gate insulating film is not limited to silicon oxide film, but other insulating films (e.g., silicon nitride film) may be used to configure a MIS transistor.

Moreover, in the above description of the embodiments, silicon (Si) is taken as an example of semiconductor. However, the semiconductor can be e.g. a compound semiconductor such as silicon carbide (SiC) or gallium nitride (GaN), or a wide bandgap semiconductor such as diamond.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a first semiconductor region of a first conductivity type;
a second semiconductor region of a second conductivity type selectively formed in one major surface of the first semiconductor region;
a third semiconductor region of the second conductivity type formed in a part of a region of the one major surface of the first semiconductor region, the second semiconductor region being not formed in the region;
a fourth semiconductor region of the first conductivity type formed in a part of a major surface of the second semiconductor region;
a first control electrode formed between the second semiconductor region and the third semiconductor region and formed via an insulating film inside a trench in contact with the fourth semiconductor region;
a first main electrode electrically connected to the second semiconductor region and the fourth semiconductor region;
a fifth semiconductor region of the first conductivity type formed on the other major surface opposite from the one major surface of the first semiconductor region;
a sixth semiconductor region of the second conductivity type formed on the fifth semiconductor region;
a second main electrode electrically connected to the sixth semiconductor region; and
a semiconductor element connected between the first main electrode and the third semiconductor region,
the semiconductor element including:
a channel using part of the first semiconductor region; and
a second control electrode configured to control the channel on the one major surface of the first semiconductor region.

2. The device according to claim 1, wherein
the channel is formed adjacent to the third semiconductor region,
a seventh semiconductor region of the second conductivity type is formed adjacent to opposite side of the channel from the third semiconductor region, and
the seventh semiconductor region and the first main electrode are electrically connected.

3. The device according to claim 1, wherein
the channel is formed adjacent to the second semiconductor region,
a seventh semiconductor region of the second conductivity type is formed adjacent to opposite side of the channel from the second semiconductor region, and
the seventh semiconductor region and the third semiconductor region are electrically connected.

4. The device according to claim 1, wherein
the sixth semiconductor region is formed on a part of the fifth semiconductor region, and
the second main electrode is electrically connected to the sixth semiconductor region and the fifth semiconductor region.

5. The device according to claim 1, wherein depth of the third semiconductor region from the one major surface is deeper than depth of the trench from the one major surface.

6. The device according to claim 1, wherein depth of the trench from the one major surface is deeper than depth of the second semiconductor region from the one major surface.

7. The device according to claim 1, wherein the first control electrode and the second control electrode are equipotential.

8. The device according to claim 1, wherein the third semiconductor region is formed along extending direction of the first control electrode.

9. The device according to claim 1, wherein the second control electrode is a gate electrode of planar type.

10. The device according to claim 2, wherein depth of the third semiconductor region from the one major surface is deeper than depth of the trench from the one major surface.

11. The device according to claim 3, wherein depth of the third semiconductor region from the one major surface is deeper than depth of the trench from the one major surface.

12. The device according to claim 2, wherein depth of the trench from the one major surface is deeper than depth of the second semiconductor region from the one major surface.

13. The device according to claim 3, wherein depth of the trench from the one major surface is deeper than depth of the second semiconductor region from the one major surface.
